(19) United States
(12) Patent Application Publication
(10) Pub. No.: US 2007/0246825 A1
(43) Pub. Date: Oct. 25, 2007

(54) HIGH FREQUENCY MODULE USING METAL-WALL AND METHOD OF MANUFACTURING THE SAME

(75) Inventors: Kwang Jae Oh, Gyunggi-do (KR); Je Hong Sung, Gyunggi-do (KR); Yoon Hyuck Choi, Gyunggi-do (KR); Tae Soo Lee, Seoul (KR)

Correspondence Address: LOWE HAUPTMAN HAM & BERNER, LLP, 1700 DIAGONAL ROAD, SUITE 300, ALEXANDRIA, VA, 22314, US

(73) Assignee: SAMSUNG ELECTRO-MECHANICS CO., LTD., Gyunggi-do (KR)

(21) Appl. No.: 11/736,201

(22) Filed: Apr. 17, 2007

(30) Foreign Application Priority Data
Apr. 21, 2006 (KR) 10-2006-0036110

(51) Int. Cl. H01L 23/34

(52) U.S. Cl. 257/728

(57) ABSTRACT

A high frequency module and a manufacturing method thereof In the module, a substrate has a ground. A plurality of surface mounted devices are mounted on the substrate. A metal wall is connected to the ground of the substrate. A resin molding hermetically seals the surface mounted devices and the metal wall, the resin molding formed to expose a top surface of the metal wall. Also, a metal film is formed on the resin molding to contact the top surface of the exposed metal wall.

### CLAIM OF PRIORITY

This application claims the benefit of Korean Patent Application No. 2006-36110 filed on Apr. 21, 2006 in the Korean Intellectual Property Office, the disclosure of which is incorporated herein by reference.

### BACKGROUND OF THE INVENTION

1. Field of the Invention

The present invention relates to a high frequency module and a manufacturing method thereof, and more particularly, to a high frequency module in which a metal shielding film is grounded by a metal wall in forming a shielding structure of the high frequency module, and a manufacturing method thereof.

2. Description of the Related Art

A high frequency module for use in a mobile telecommunication device such as a mobile phone is constructed of a high frequency circuit including a high frequency semiconductor device and a periphery circuit that are formed on a substrate thereof.

In general, current propagating in an electronic device induces electric field and magnetic field therearound, thereby generating a space due to electric potential difference. Here, the electric field changes with time and generates electric magnetic field therearound. That is, regardless of the induction of the device, current flows to create electromagnetic noise, which is an unnecessary energy.

Such electromagnetic noise, if transferred to other devices through a path, leads to degradation in performance and malfunction thereof.

To shield the electromagnetic noise and protect the semiconductor device, a shielding technique for forming a shielding film has been employed.

FIG. 1a and 1b illustrate a shielding structure according to the prior art.

FIG. 1a is a cross-sectional view illustrating a high frequency module having a surface mounting device 12 on a substrate 11 shielded via a metal cap 13.

In the conventional shielding structure of the high frequency module shown in FIG. 1a, the metal cap 13, if reduced in its thickness, cannot remain strong but is easily warped, potentially contacting the high frequency device. To prevent short-circuit caused by contact between the metal cap 13 and the high frequency device, a certain space should be preserved under the metal cap 13 to accommodate the metal cap 13 that may be warped. For example, the metal cap should be formed to a thickness of 100 μm, and an inner space thereof should be designed to a thickness of 80 μm. This physical volume stands in the way of miniaturization of the high frequency module.

FIG. 1b is a cross-sectional view illustrating a high frequency module in which a shielding film is formed via a metal film 15 after resin molding.

In FIG. 1b, a high frequency semiconductor device 12 is mounted on the substrate 11 and resin molded to be hermetically sealed. Then the shielding film is formed on a surface of a mold 14 using the metal film 15.

This leads to smaller physical volume compared to a case where the metal cap is adopted. Yet, the metal film formed on the molding is not connected to a ground of the substrate, thus insignificant in terms of shielding effects.

### SUMMARY OF THE INVENTION

The present invention has been made to solve the foregoing problems of the prior art and therefore an aspect of the present invention is to provide a compact high frequency module for enhancing effects of shielding an electromagnetic wave of a shielding metal film formed on a molding.

Another aspect of the invention is to provide a method for manufacturing the high frequency module.

According to an aspect of the invention, the high frequency module includes a substrate having a ground; a plurality of surface mounted devices mounted on the substrate; a metal wall connected to the ground of the substrate; a resin molding hermetically sealing the surface mounted devices and the metal wall, the resin molding formed to expose a top surface of the metal wall; and a metal film formed on the resin molding to contact the top surface of the exposed metal wall.

The metal wall is disposed on the substrate to spatially separate some of the surface mounted devices from the others. The metal wall has a bending depending on a mounting position of the surface mounted devices. Here, the metal wall has both ends extending to edges of the substrate, respectively. The metal wall disposed between the surface mounted devices serves to block interference from an electromagnetic wave radiated from the devices.

The metal wall has an indentation for serving as a pathway of a liquid.

The indentation is formed in an upper part of the metal wall.

Preferably, the indentation is formed at a height greater than a mounting height of the surface mounted devices.

Preferably, the metal wall has a lightning rod structure with a planar main board and a plurality of fingers attached onto the planar main board. This structure enables a liquid molding material to flow in with minimal interference with the metal wall in a process of injecting the liquid molding material to form the molding.

According to another aspect of the invention, the method for manufacturing a high frequency module includes:

mounting a plurality of surface mounted devices on a substrate having a ground;

disposing a metal wall on the substrate to contact the ground, the metal wall having a height exceeding a mounting height of the surface mounted devices;

forming a molding hermetically sealing the surface mounted devices and the metal wall while exposing a top surface of the metal wall; and

forming a metal film on the molding to contact the top surface of the exposed metal wall.

Preferably, the mold-forming step includes:

injecting a liquid molding material; and

upon curing of the liquid molding material, polishing the cured molding material to expose the top surface of the metal wall in a top surface of the molding.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a and 1b are cross-sectional views illustrating a conventional shielding structure;

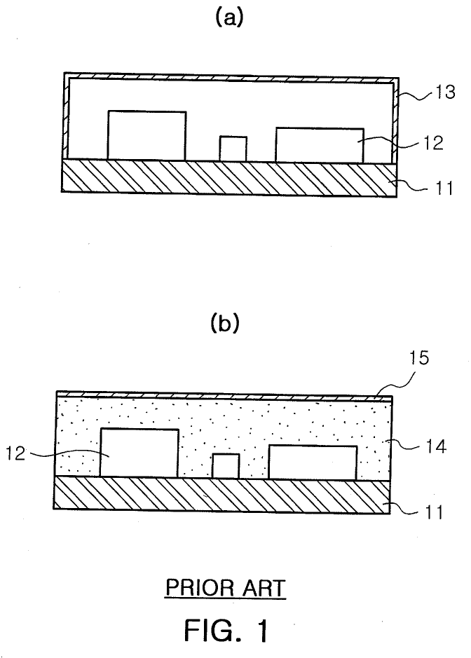

FIG. 2a is a perspective view illustrating a high frequency module with a metal wall structure according to an embodiment of the invention and FIG. 2b is a front elevation view illustrating the metal wall;

FIG. 3a is an exploded perspective view illustrating a high frequency module according to another embodiment of the invention and FIG. 3b is a plan view illustrating the high frequency module; and

FIGS. 4a to 4d are views sequentially illustrating a method for manufacturing a high frequency module according to the invention.

### DETAILED DESCRIPTION OF THE PREFERRED EMBODIMENT

Exemplary embodiments of the present invention will now be described in detail with reference to the accompanying drawings.

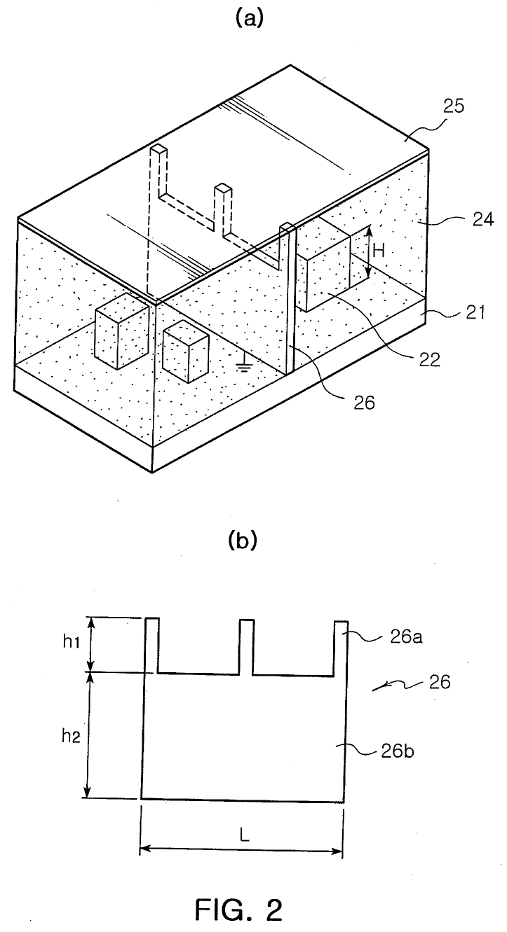

FIG. 2a is a perspective view illustrating a high frequency module using a metal wall according to an embodiment of the invention. FIG. 2b is a front elevation view illustrating the metal wall.

Referring to FIG. 2a, a substrate 21 is provided with semiconductor devices 22 and a metal wall 26 thereon. A metal film 25 is formed on a resin molding 24 sealing the devices 22 and the metal wall 26.

A ground (not illustrated) is formed inside or on a surface of the substrate.

The devices 22 mounted on the substrate 21 are connected to one another by a circuit (not illustrated) on the substrate 21, performing various functions.

Also, the resin molding 24 hermetically seals a high frequency device or electronic product, thereby improving moisture-resistant or impact-resistant characteristics over a conventional metal cap. Moreover, the metal cap necessitates a soldering process but an insulating resin precludes a need for such a soldering process. A material for the molding 24 is not particularly limited unless departing from a scope of the invention. The molding 24 can be made of a thermosetting resin such as an epoxy resin.

A method for forming the molding 24 is not particularly limited either, and includes examples of transfer molding, printing and injection molding. Since the metal wall has an indentation formed therein according to the invention, preferably, the molding is formed by injecting a liquid molding material.

A metal film 25 formed on the molding 24 can be formed by various methods such as deposition, sputtering and plating. The metal film 25 is made of one selected from a group consisting of gold, silver, copper and nickel. The metal film may be of a single layer, but a multi-layer without being limited thereto. In FIG. 2(a), the metal wall 26 electrically connects the metal film 25 with the ground of the substrate 21. The metal film 25 alone produces effects of shielding an electromagnetic wave to a certain degree. But the metal film 25 connected to the ground improves the shielding effects.

The metal wall 26 has both ends extending to edges of the substrate 21. Furthermore, the metal wall 26 is disposed to transverse the substrate, thereby spatially separating some (or one) of the surface mounted devices 22 from the others. This blocks cross-interference from electromagnetic waves radiated from the semiconductor devices 22.

The metal wall 26 features a lightning rod structure having a planar main board in a lower part thereof and a plurality of fingers in an upper part thereof, which define a plurality of indentations. These indentations work beneficially when the liquid molding material is injected, after the metal wall 26 is disposed, to mold the semiconductor devices. That is, the molding material can flow through the indentations, thereby assuring the molding material to be evenly distributed on the substrate 21 regardless of from where the molding material is injected.

Preferably, the metal wall 26 is disposed on the substrate 21 to spatially separate some of the surface mounted devices from the others, thereby serving as a separation screen. The indentations may be formed in an upper part of the metal wall 26 at a height greater than a mounting height of the surface mounted devices. This maximizes effects of shielding electromagnetic waves resulting from the metal wall 26, also enabling the molding material to flow.

FIG. 2b is a front elevation view illustrating the metal wall 26 in the high frequency module of FIG. 2a.

Referring to FIG. 2b, the metal wall 26 includes a lower part, i.e., a planar main board 26b and an upper part having a plurality of finger boards 26a. The lower part 26b of the metal wall has a height of h₂ and the upper part 26a thereof has a height of h₁.

The lower part 26b of the metal wall 26 is connected to the ground of the substrate 21. The upper part 26a of the metal wall 26 has a top surface in contact with the metal film 25 so that the metal film 25 is electrically connected to the ground.

The metal wall 26 itself can be improved in effects of shielding electromagnetic wave from the mounting devices. Here, preferably, the metal wall 26 has a width L in excess of that of the surface mounted devices 22 and the lower part 26b of metal wall has a height h₂ in excess of that H of the surface mounted devices.

Moreover, the indentations in the upper part 26a of the metal wall may be variously configured.

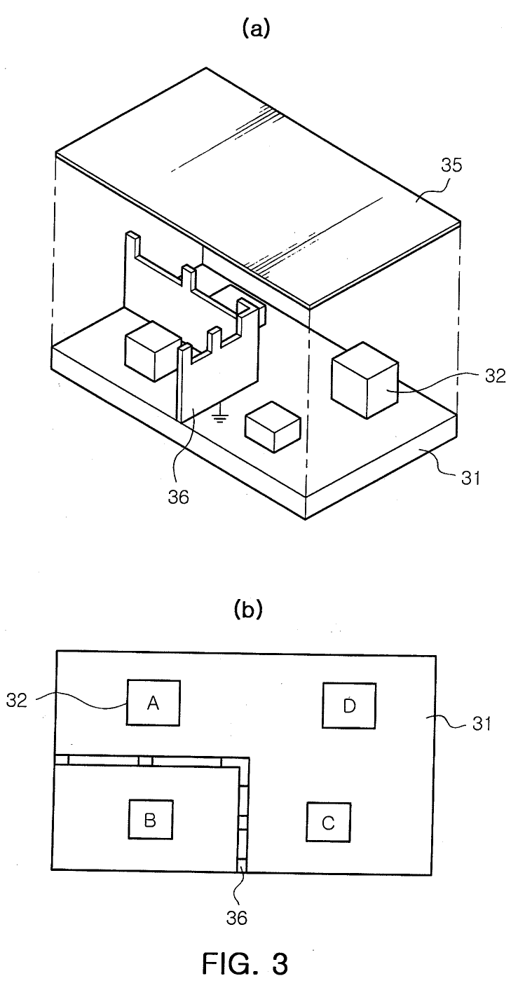

FIG. 3a is an exploded perspective view illustrating a high frequency module according to another embodiment of the invention and FIG. 3b is a plan view illustrating the high frequency module.

Referring to FIGS. 3a and 3b, a metal wall 36 has a bending to be located between a mounting device A and a mounting device B, and between the mounting device B and a mounting device C.

Also, according to this embodiment, a resin molding is necessarily formed to seal mounting devices 32 on a substrate 31, but not depicted in FIGS. 3a and 3b for explanatory convenience since FIGS. 3a and 3b are merely illustrative of a structure of the metal wall. Also, the metal film 35 should contact a top surface of the metal wall 36. But in FIG. 3a, the metal film 35 is spaced apart from the top surface of the metal wall 36. FIG. 3b is a plan view in which the metal film 35 is removed.

The metal wall 36 with such a bending further ensures some of the surface mounted devices 32 to be isolated from the others, thereby elevating effects of shielding electromagnetic wave of the mounting devices.

As described above, the metal wall disposed on the substrate can be variously configured.

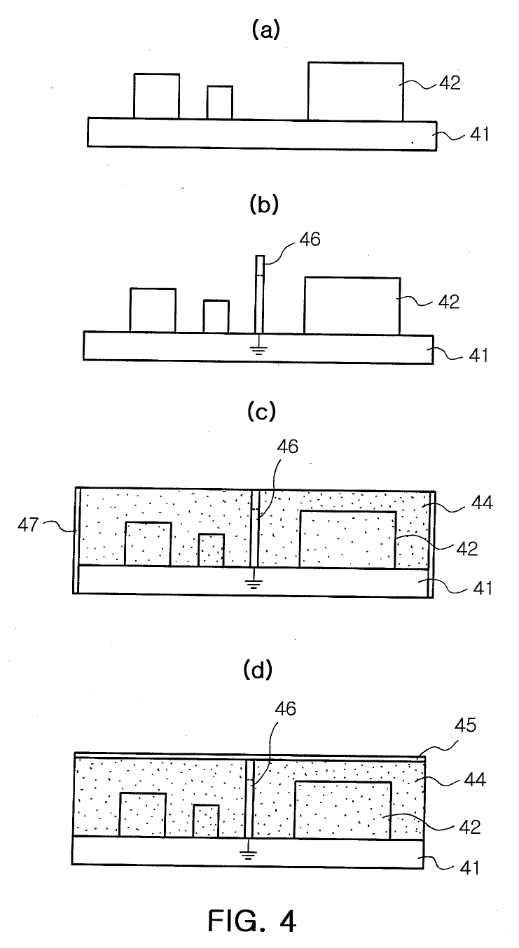

FIGS. 4a to 4d are views sequentially illustrating a method for manufacturing a high frequency module according to an embodiment of the invention.

Referring to FIG. 4a, semiconductor devices 42 are surface-mounted on a substrate 41 having a ground therein. Here, the devices make up an electrically connected circuit.

Referring to FIG. 4b, a metal wall 46 is disposed to connect to the ground of the substrate 41. The metal wall 46 preferably has a height exceeding a mounting height of the surface mounted devices 42 to necessarily connect to a metal film after molding.

The metal wall 46 may be disposed on the substrate 41 to spatially separate some of the surface mounted devices from the others. This allows the metal wall 46 to block interference from electromagnetic waves radiated from the surface mounted devices.

Preferably, the metal wall 46 has both ends extending to edges of the substrate and may have a bending depending on a mounting position of the surface mounted devices 42.

Furthermore, the metal wall 46 may have indentations for serving as a pathway of a liquid material. This enables the molding resin to be evenly distributed regardless of from where the liquid molding resin is injected during molding.

Preferably, the indentations are located in an upper part of the metal wall at a height greater than a mounting height of the surface mounted devices 42. This allows the molding resin to flow without any interference and maximizes effects of shielding electromagnetic waves among the surface mounted devices.

Referring to FIG. 4c, mold frames 47 are disposed at both sides of the substrate 41, respectively, to prevent the liquid molding resin from flowing outside the substrate. Then a molding material is injected inside the mold frames 47 to form a molding 44.

Here, a top surface of the metal wall 46 is exposed in a top surface of the molding 44. Preferably, the liquid molding material is injected into the mold frames 47 to be cured, and the liquid molding material cured is polished so that the top surface of the metal wall 46 is exposed in the top surface of the molding 44.

Referring to FIG. 4d, the mold frames 47 are removed and a metal film 45 is formed on the molding 44 to shield electromagnetic waves. Here, the metal film 45 is formed by various methods such as deposition, sputtering and plating.

As set forth above, according to exemplary embodiments of the invention, a high frequency module has a metal wall formed inside a molding to connect a metal film formed on the molding to a ground of a substrate, thereby further ensuring the metal film to shield electromagnetic waves.

In addition, the metal wall is disposed on the substrate to spatially separate some of surface mounted devices from the others, thereby shielding electromagnetic waves from the mounting devices. In addition, indentations are formed in the metal wall disposed inside the molding so that the metal wall can be a minimal hindrance to a molding process.

While the present invention has been shown and described in connection with the preferred embodiments, it will be apparent to those skilled in the art that modifications and variations can be made without departing from the spirit and scope of the invention as defined by the appended claims.

What is claimed is:

1. A high frequency module comprising:
a substrate having a ground;
a plurality of surface mounted devices mounted on the substrate;
a metal wall connected to the ground of the substrate;
a resin molding hermetically sealing the surface mounted devices and the metal wall, the resin molding formed to expose a top surface of the metal wall; and
a metal film formed on the resin molding to contact the top surface of the exposed metal wall.

2. The high frequency module according to claim 1, wherein the metal wall is disposed on the substrate to spatially separate some of the surface mounted devices from the others.

3. The high frequency module according to claim 2, wherein the metal wall has both ends extending to edges of the substrate, respectively.

4. The high frequency module according to claim 3, wherein the metal wall has a bending depending on a mounting position of the surface mounted devices.

5. The high frequency module according to claim 1, wherein the metal wall has an indentation for serving as a pathway of a liquid.

6. The high frequency module according to claim 5, wherein the indentation is formed in an upper part of the metal wall.

7. The high frequency module according to claim 6, wherein the indentation is formed at a height greater than a mounting height of the surface mounted devices.

8. The high frequency module according to claim 7, wherein the metal wall comprises a lightning rod structure having a planar main board and a plurality of fingers attached onto the planar main board.

9. A method for manufacturing a high frequency module comprising:
mounting a plurality of surface mounted devices on a substrate having a ground;
disposing a metal wall on the substrate to contact the ground, the metal wall having a height exceeding a mounting height of the surface mounted devices;
forming a molding hermetically sealing the surface mounted devices and the metal wall while exposing a top surface of the metal wall; and
forming a metal film on the molding to contact the top surface of the exposed metal wall.

10. The method according to claim 9, wherein the molding-forming step comprises:
injecting a liquid molding material; and
upon curing of the liquid molding material, polishing the cured molding material to expose the top surface of the metal wall in a top surface of the molding.

11. The method according to claim 9, wherein the metal wall is disposed on the substrate to spatially separate some of the surface mounted devices from the others.

12. The method according to claim 11, wherein the metal wall has both ends extending to edges of the substrate, respectively.

13. The method according to claim 12, wherein the metal wall has a bending depending on a mounting position of the surface mounted devices.

14. The method according to claim 9, wherein the metal wall has an indentation for serving as a pathway of a liquid.

15. The method according to claim 14, wherein the indentation is formed in an upper part of the metal wall.

16. The method according to claim 15, wherein the indentation is formed at a height greater than a mounting height of the surface mounted devices.

17. The method according to claim 16, wherein the metal wall comprises a lightning rod structure having a planar main board and a plurality of fingers attached onto the main board.
